(19) United States
(12) Patent Application Publication
(10) Pub. No.: US 2021/0242248 A1
(43) Pub. Date: Aug. 5, 2021

(54) DOUBLE-SIDED TFT PANEL, METHOD FOR MANUFACTURING THE SAME, AND DISPLAY DEVICE

(71) Applicant: CHONGQING KONKA PHOTOELECTRIC TECHNOLOGY RESEARCH INSTITUTE CO., LTD., Chongqing (CN)

(72) Inventors: Pofu CHEN, Chongqing (CN); Ying-chi WANG, Chongqing (CN); Jiang CAO, Chongqing (CN)

(21) Appl. No.: 17/235,696

(22) Filed: Apr. 20, 2021

Related U.S. Application Data
(63) Continuation of application No. PCT/CN2019/126674, filed on Dec. 19, 2019.

(51) Int. Cl. H01L 27/12; H01L 25/075; H01L 33/62; H01L 29/786

(52) U.S. Cl. CPC H01L 27/1218; H01L 25/0753; H01L 33/62; H01L 2933/0066; H01L 27/124; H01L 29/78675; H01L 27/1266; H01L 27/1222

(57) ABSTRACT

A method for manufacturing a double-sided thin film transistor (TFT) panel, a double-sided TFT panel, and a display device having the double-sided TFT panel are provided. The method includes the following. Two substrates are provided, and a TFT panel is formed on each of the two substrates. A support membrane is attached to a side of each TFT panel away from the substrate corresponding to the TFT panel. The substrate corresponding to each TFT panel is peeled off. The double-sided TFT panel is formed, by attaching a side of one of the two TFT panels to a side of the other one of the two TFT panels. A conductive hole is defined on the double-sided TFT panel, where the conductive hole is used for making electrodes on the two TFT panels communicate with each other.

### CROSS-REFERENCE TO RELATED APPLICATIONS

This application is a continuation of International Application No. PCT/CN2019/126674, filed on Dec. 19, 2019, the entire disclosure of which is incorporated herein by reference.

### TECHNICAL FIELD

This disclosure relates to the field of display technology, and more particularly to a double-sided thin film transistor (TFT) panel, a method for manufacturing a double-sided TFT panel, and a display device.

### BACKGROUND

In the field of display technology, flat panel display technologies such as liquid crystal displays (LCD) and organic light emitting diodes (OLED) display are gradually replacing cathode ray tube (CRT) displays. An OLED display has many advantages such as self-luminescence, low driving voltage, high luminous efficiency, short response time, high resolution and contrast, viewing angle close to 180°, wide operating temperature range, capabilities of flexible display and large-area full-color display, etc. The OLED display is widely recognized by the industry as the most promising display device.

An existing flexible OLED display generally includes a flexible thin film transistor (TFT) panel and an OLED device disposed on the flexible TFT panel.

In the related art, since low temperature poly-silicon (LTPS) panels are all manufactured on a single side, signal lines and drivers on the flexible TFT panel can only be arranged on one side of the flexible TFT panel. As resolution of products becomes higher, wiring will become denser. When signal lines and drivers are arranged, the flexible TFT panel does not have enough space for arrangement.

### SUMMARY

To this end, implementations provide a double-sided thin film transistor (TFT) panel, a method for manufacturing a double-sided TFT panel, and a display device.

In order to solve the above technical problem, technical solutions of implementations are as follows.

In a first aspect, a method for manufacturing a double-sided TFT panel is provided. The method includes the following. Two substrates are provided, and a TFT panel is formed on each of the two substrates (e.g., a TFT panel grows on each of the two substrates). A support membrane is attached to a side of each TFT panel away from the substrate corresponding to the TFT panel. The substrate corresponding to each TFT panel is peeled off. The double-sided TFT panel is formed, by attaching a side, from which the substrate is peeled off, of each of the two TFT panels. A conductive hole is defined on the double-sided TFT panel, where the conductive hole is used for making electrodes on the two TFT panels communicate with each other.

In a second aspect, a double-sided TFT panel is provided. The double-sided TFT panel includes two TFT panels, a drive circuit, and a conductive hole. A side of one of the two TFT panels is attached to a side of the other one of the two TFT panels. The drive circuit is disposed on any one of the two TFT panels of the double-sided TFT panel and shared with the other one of the two TFT panels of the double-sided TFT panel. The conductive hole is defined on the double-sided TFT panel, where the conductive hole is used for making electrodes on the double-sided TFT panel communicate with each other.

In a third aspect, a display device is provided. The display device includes a housing and the double-sided TFT panel described in the second aspect. The double-sided TFT panel is disposed inside the housing.

### BRIEF DESCRIPTION OF THE DRAWINGS

FIG. 1 is a schematic flowchart of a method for manufacturing a double-sided TFT panel according to implementations.

FIG. 2A is a schematic diagram illustrating a first state of a process of manufacturing a double-sided TFT panel according to implementations.

FIG. 2B is schematic diagrams illustrating a second state of a process of manufacturing a double-sided TFT panel according to implementations.

FIG. 2C is schematic diagrams illustrating a third state of a process of manufacturing a double-sided TFT panel according to implementations.

FIG. 2D is schematic diagrams illustrating a fourth state of a process of manufacturing a double-sided TFT panel according to implementations.

FIG. 2E is schematic diagrams illustrating a fifth state of a process of manufacturing a double-sided TFT panel according to implementations.

FIG. 2F is schematic diagrams illustrating a sixth state of a process of manufacturing a double-sided TFT panel according to implementations.

FIG. 2G is schematic diagrams illustrating a seventh state of a process of manufacturing a double-sided TFT panel according to implementations.

FIG. 2H is schematic diagrams illustrating an eighth state of a process of manufacturing a double-sided TFT panel according to implementations.

FIG. 3 is a schematic diagram of a double-sided TFT panel according to implementations.

FIG. 4 is a schematic diagram of a display device having the double-sided TFT panel according to implementations.

### DETAILED DESCRIPTION

In order for a clearer and more accurate understanding of implementations, implementations will be described in detail with reference to the accompanying drawings. The accompanying drawings illustrate examples of implementations, in which the same reference numerals denote the same components. It can be understood that, a scale illustrated in the drawings is not a scale of the actual implementation of implementations, which is for illustrative purposes only and not drawn according to the original size.

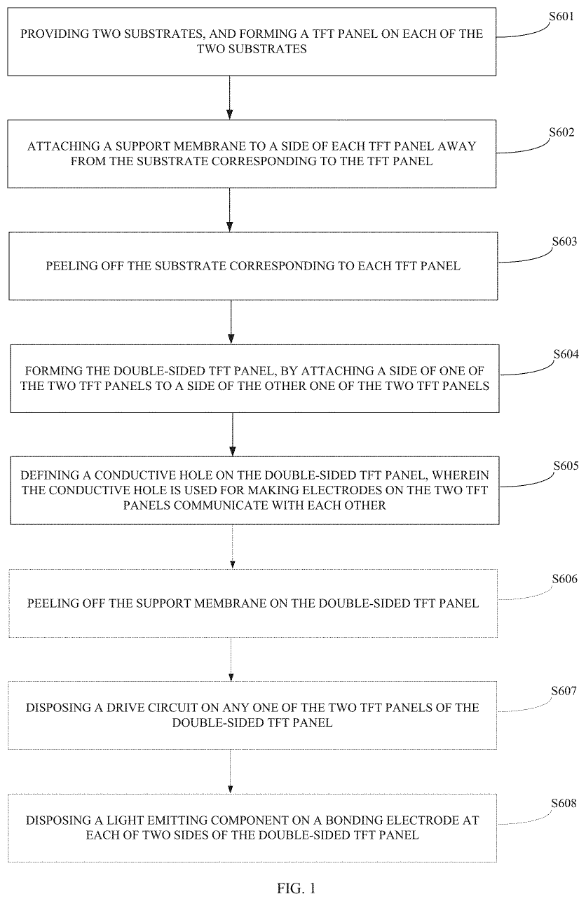

FIG. 1 is a schematic flowchart of a method for manufacturing a double-sided TFT panel 6 according to implementations. The method includes the following.

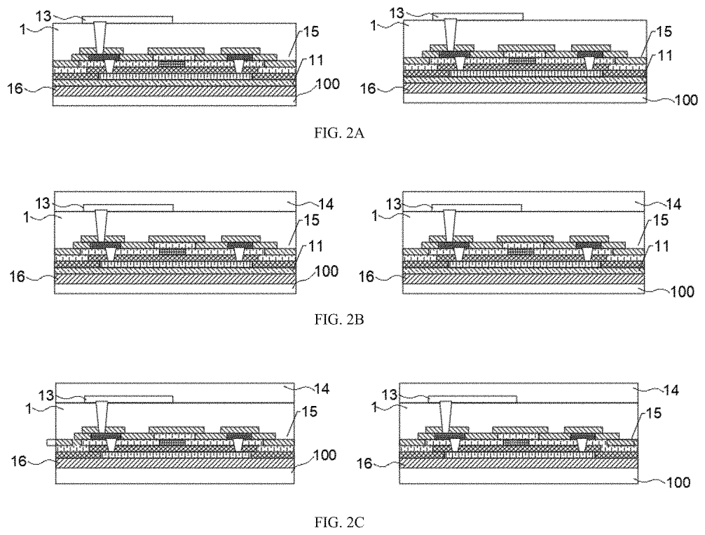

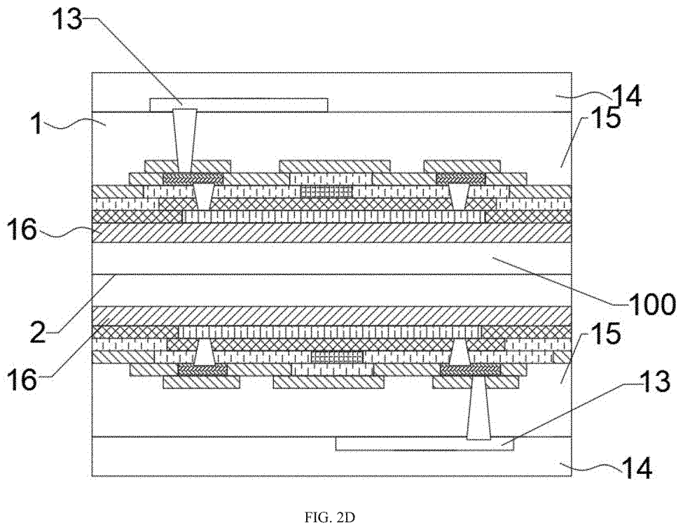

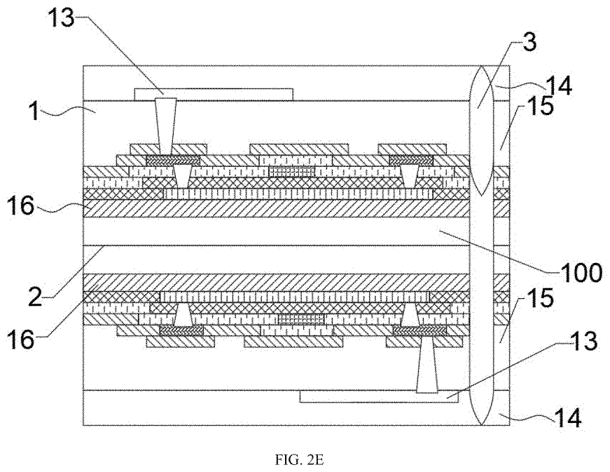

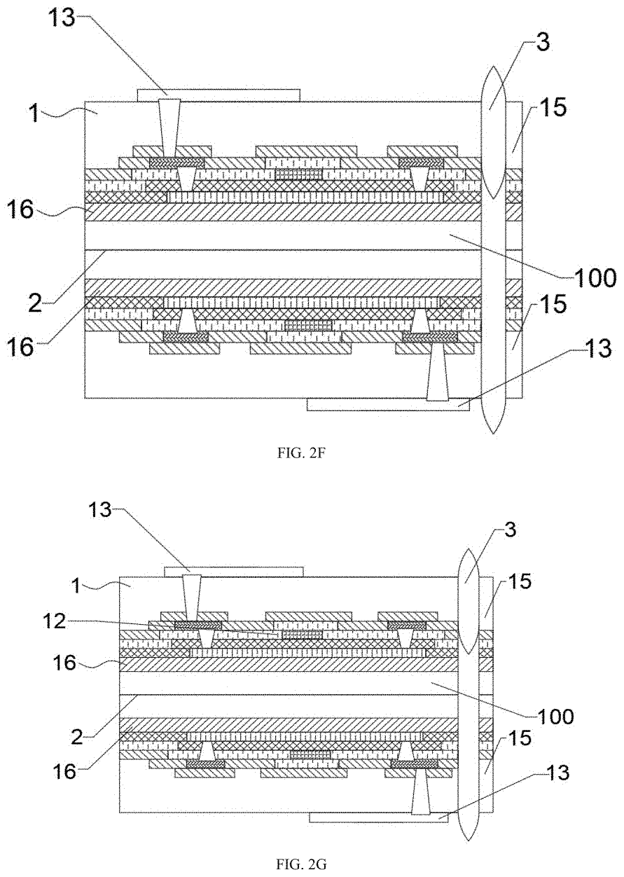

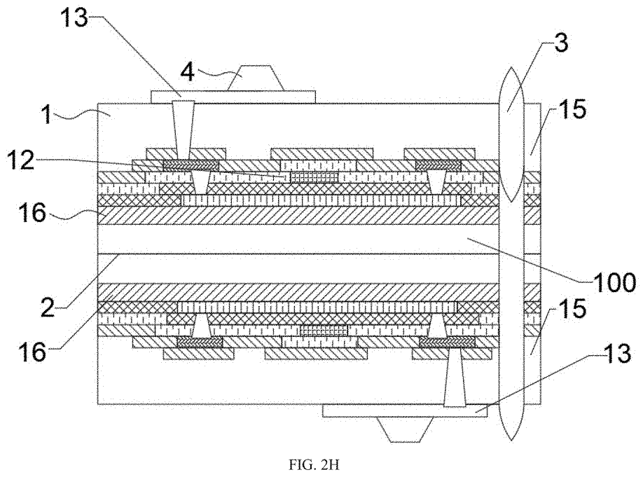

At block S601, two substrates 11 are provided, and a TFT panel 1 is formed on each of the two substrates 11. As illustrated in FIG. 2A, the two substrates 11 are each a flexible sapphire substrate 11. The substrate 11 may be transparent or non-transparent. If the substrate 11 is required to be transparent, the substrate 11 may be made of a glass material. The glass material can be, but is not limited, to a glass material mainly composed of SiO₂.

The substrate 11 is a copper clad laminate. Manufacturing of a single-sided printed board or a double-sided printed board includes hole processing, electroless copper plating, copper electroplating, etching, and the like which are selectively performed on the substrate 11 (that is, copper clad laminate), to obtain a required circuit pattern. As to manufacturing of another type of multilayer printed board, a thin-core copper clad laminate is used as a base, on which a conductive pattern layer and a prepreg are alternately bonded together through one-time lamination, to achieve interconnections among more than three layers of conductive patterns. The substrate 11 has three functions, which are conduction, insulation, and support. The performance, quality, processability in manufacturing, manufacturing cost, and manufacturing capability of a printed board depend largely on the material of the substrate 11.

As an example, the flexible sapphire substrate 11 can also be made of a plastic transparent material. The plastic glass material can be, but is not limited to, polyethersulfone (pes), polyacrylate (par), polyetherimide (pei), polyethylene naphthoate (pet), polyphenylene sulfide (pps), polyα-acrylate, polyimide, polycarbonate (pc), cellulose triacetate (TAC), cellulose acetate propionate (CAP), etc. If the flexible sapphire substrate 11 is required to be non-transparent, it can be made of a metal material. The metal material may be, but is not limited to, copper, aluminum, or other flexible metal materials.

Taking an LTPS TFT panel 1 as an example, the TFT panel 1 includes a drive circuit 12 disposed at one side of the substrate 11, a bonding electrode 13, a flat layer 15, an insulation layer 16, and a buffer layer 100. The buffer layer 100, the insulation layer 16, and the flat layer 15 are sequentially disposed. The drive circuit 12 is disposed between the insulation layer 16 and the flat layer 15 through a damascene process. The flat layer 15 covers a side of the drive circuit 12 away from the insulation layer 16, and a side of the flat layer 15 away from the insulation layer 16 forms a flat surface.

The drive circuit 12 may include a TFT, a data line, a scan line, etc. A gate, a source, and a drain of the TFT are mainly made of a metal material doped with a conductive semiconductor material. The metal material can be, but is not limited to, copper, aluminum, tungsten, gold, silver, etc. The conductive semiconductor material may be, but is not limited to, polysilicon. The drive circuit 12 may be, but is not limited to, a 2T1C circuit.

The flat layer 15 is made of an insulation material. The insulation material may include, but is not limited to, SiO₂, Si₃N₄, HfO₂, SiON, TiO₂, TaO₃, SnO₂, etc.

The insulation layer 16 includes a gate insulation layer 16 and a non-gate insulation layer 16. The insulation layer 16 is made of an inorganic material. The inorganic material may be, but is not limited to, an oxide material (such as SiO₂), a nitride material (such as SiN), etc.

The buffer layer 100 is laid on a side of the substrate 11, which is used to planarize the substrate 11 and on the other hand, prevent impurities or moisture from penetrating through the substrate 11. The buffer layer 100 may be made of an inorganic material. The inorganic material can be, but is not limited to, silicon oxide, silicon nitride, aluminum oxide, aluminum nitride, titanium oxide, and the like. The buffer layer 100 can also be made of an organic material. The organic material can be, but is not limited to, polyimide, polyamide, or propylene.

At block S602, a support membrane 14 is attached to a side of each TFT panel 1 away from the substrate 11 corresponding to the TFT panel 1, as illustrated in FIG. 2A-FIG. 2B. The support membrane 14 can be, but is not limited to, a polysulfone porous membrane. Alternatively, the support membrane 14 may be a support membrane 14 which made of other materials and has a support function, which is not limited herein.

At block S603, the substrate 11 corresponding to each TFT panel 1 is peeled off, as illustrated in FIG. 2B-FIG. 2C. In some implementations, the manner of peeling off the substrate 11 may be, but is not limited to, laser processing. Alternatively, the substrate 11 may be peeled off by heating the substrate 11, such that the substrate 11 can be detached from the double-sided TFT panel 6. Alternatively, the substrate 11 may be peeled off by irradiating ultraviolet ray onto the substrate 11, such that the substrate 11 can be detached from the double-sided TFT panel 6. The substrate 11 may also be peeled off in other manners which will lead to a similar peeling effect.

At block S604, the double-sided TFT panel 6 is formed, by attaching a side of the one of the two TFT panels 1 to a side of the other one of the two TFT panels 1. As illustrated in FIG. 2C-FIG. 2D, in some implementations, the double-sided TFT panel 6 is formed, by attaching, with an adhesive insulation material 2, a side of one of the two TFT panels 1 at which the substrate 11 corresponding to the one TFT panel 1 is peeled off, to a side of the other one of the two TFT panels 1 at which the substrate 11 corresponding to the other one TFT panel 1 is peeled off. In some implementations, the adhesive insulation material 2 may be, but is not limited to, a polyimide film. Alternatively, the adhesive insulation material 2 may also be other types of adhesive insulation materials. According to different materials of the adhesive insulation material 2, the adhesive insulation material 2 may include an ethylene-propylene rubber self-adhesive tape, an ethylene-propylene rubber and butyl rubber waterproof tape, a silica gel tape, etc. According to different functions of the adhesive insulation material 2, the adhesive insulation material 2 may include a high-pressure rubber self-adhesive tape, a low-pressure rubber self-adhesive tape, a waterproof tape, a semi-conductive tape, an electrical stress control tape, an arc-resistant silica gel tape, etc.

At block S605, a conductive hole 3 is defined on the double-sided TFT panel 6, where the conductive hole 3 is used for making electrodes on the two TFT panels 1 communicate with each other. As illustrated in FIG. 2D-FIG. 2E, the conductive hole 3 may be defined through manual drilling or electrical drilling. When only a few conductive holes 3 are required, manual drilling can be adopted. When a large number of conductive holes 3 are required, electrical drilling can be adopted.

In some implementations, the conductive hole 3 is filled with a metal-plated material or a conductive glass material. The conductive hole 3 is used for making the electrodes on the two TFT panels 1 communicate with each other. If the conductive hole 3 is filled with a metal-plated material, the metal-plated material can be, but is not limited to, gold, silver, or copper. If the conductive hole 3 is filled with a conductive glass material, the conductive glass may include a volume conductive glass and a surface conductive layer glass. The volume conductive glass contains an alkaline oxide, a silicon oxide, and a titanium oxide. The surface conductive layer glass is manufactured by vapor-depositing a metal film (such as gold, platinum, etc., and the metal film has a thickness of less than 10 nm) on a transparent glass surface, or by spraying a metal oxide conductive film (such as tin, indium, etc.) on a heated glass surface. Therefore, a conductive glass is a glass which is low in resistance and high in conductivity.

At block S606, the support membrane 14 on the double-sided TFT panel 6 is peeled off. In other words, the support membrane 14 on each of the two TFT panels 1 is peeled off. As illustrated in FIG. 2E-FIG. 2F, the manner of peeling off the support membrane 14 may be, but is not limited to, laser processing. Alternatively, the support membrane 14 may be peeled off by heating the support membrane 14, such that the support membrane 14 can be detached from the double-sided TFT panel 6. Alternatively, the support membrane 14 may be peeled off by irradiating ultraviolet ray onto the support membrane 14, such that the support membrane 14 can be detached from the double-sided TFT panel 6. The support membrane 14 may also be peeled off in other manners which will lead to a similar peeling effect.

At block S607, the drive circuit 12 is disposed on any one of the TFT panel 1 of the double-sided TFT panel 6, where the drive circuit 12 is shared with the other one of the TFT panel 1 of the double-sided TFT panel 6. As illustrated in FIG. 2F-FIG. 2G, when the drive circuit 12 is disposed on any one of the TFT panel 1 of the double-sided TFT panel 6, the other one of the TFT panel 1 of the double-sided TFT panel 6 shares the drive circuit 12. Signal lines and data lines of the drive circuit 12 can be distributed to both of the two TFT panels 1, which is possible to reduce arrangement of signal lines and data lines in a non-display region and on the other hand, reduce the area of the non-display region.

At block S608, a light emitting component 4 is disposed on the bonding electrode 13 at each of two sides of the double-sided TFT panel 6, as illustrated in FIG. 2G-FIG. 2H.

The light emitting component 4 can be, but is not limited to, a micro light emitting diode (LED), and the size of the micro LED is in the order of micrometers. In addition, the size of the micro LED is less than 100 micrometers. The micro LED on the double-sided TFT panel 6 can emit light under the action of the drive circuit 12.

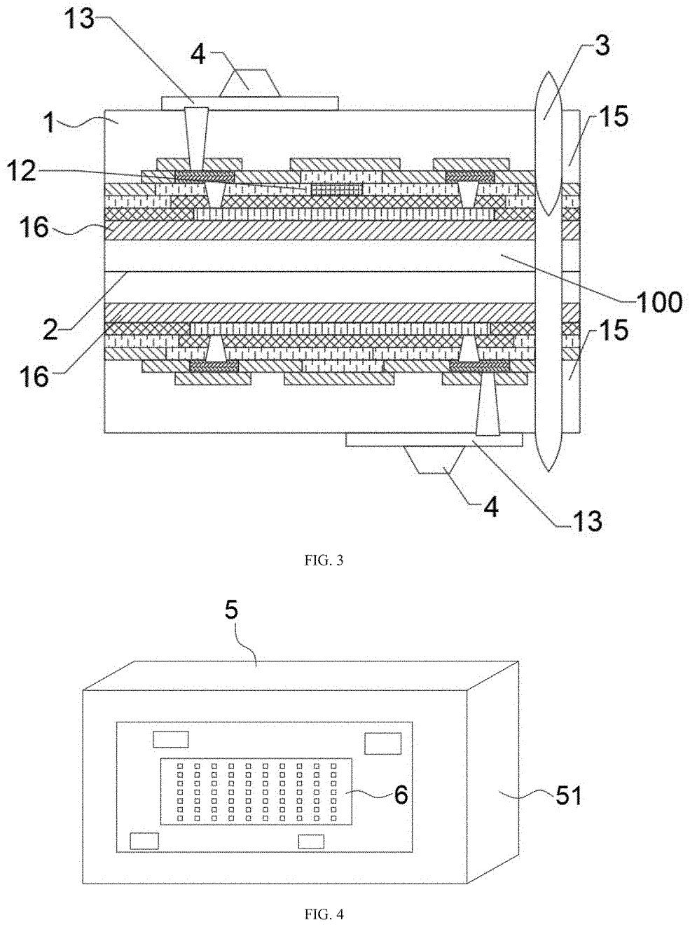

FIG. 3 is a schematic diagram of a double-sided TFT panel 6 according to implementations. The double-sided TFT panel 6 includes two TFT panels 1, a drive circuit 12, and a conductive hole 3. A side of one of the two TFT panels 1 is attached to a side of the other one of the two TFT panels 1, to form the double-sided TFT panel 6. The drive circuit 12 is disposed on any one of the two TFT panels 1 of the double-sided TFT panel 6, where the drive circuit 12 is shared with the other one of the two TFT panels 1 of the double-sided TFT panel 6. The conductive hole 3 is defined on the double-sided TFT panel 6, where the conductive hole 3 is used for making electrodes on the double-sided TFT panel 6 communicate with each other. The double-sided TFT panel 6 can achieve double-sided display. According to implementations, the double-sided TFT panel 6 can be located in an electronic device, such as a mobile phone, a computer, and other electronic devices having an LED display.

According to implementations, the TFT panel 1 is an LTPS TFT panel 1. The TFT panel 1 includes the drive circuit 12 disposed at one side of the substrate 11, a bonding electrode 13, a flat layer 15, an insulation layer 16, and a buffer layer 100. The buffer layer 100, the insulation layer 16, and the flat layer 15 are sequentially disposed. The drive circuit 12 is disposed between the insulation layer 16 and the flat layer 15 through a damascene process. The flat layer 15 covers a side of the drive circuit 12 away from the insulation layer 16, and a side of the flat layer 15 away from the insulation layer 16 forms a flat surface.

The drive circuit 12 may include a TFT, a data line, a scan line, etc. A gate, a source, and a drain of the TFT are mainly made of a metal material doped with a conductive semiconductor material. The metal material can be, but is not limited to, copper, aluminum, tungsten, gold, silver, etc. The conductive semiconductor material may be, but is not limited to, polysilicon. The drive circuit 12 may be, but is not limited to, a 2T1C circuit.

The flat layer 15 is made of an insulation material. The insulation material may include, but is not limited to, SiO₂, Si₃N₄, HfO₂, SiON, TiO₂, TaO₃, SnO₂, etc.

The insulation layer 16 includes a gate insulation layer 16 and a non-gate insulation layer 16. The insulation layer 16 is made of an inorganic material. The inorganic material may be, but is not limited to, an oxide material (such as SiO₂), a nitride material (such as SiN), etc.

The buffer layer 100 is laid on a side of the substrate 11, which is used to planarize the substrate 11 and on the other hand, prevent impurities or moisture from penetrating through the substrate 11. The buffer layer 100 may be made of an inorganic material. The inorganic material can be, but is not limited to, silicon oxide, silicon nitride, aluminum oxide, aluminum nitride, titanium oxide, and the like. The buffer layer 100 can also be made of an organic material. The organic material can be, but is not limited to, polyimide, polyamide, or propylene.

A side of one of the two TFT panels 1 is attached to a side of the other one of the two TFT panels 1. The drive circuit 12 is disposed on any one of the TFT panel 1 of the double-sided TFT panel 6, where the drive circuit 12 is shared with the other one of the TFT panel 1 of the double-sided TFT panel 6. Signal lines and data lines of the drive circuit 12 can be distributed to both of the two TFT panels 1, which is possible to reduce arrangement of signal lines and data lines in a non-display region and on the other hand, reduce the area of the non-display region.

The conductive hole 3 is defined on the double-sided TFT panel 6, where the conductive hole 3 is used for making electrodes on the double-sided TFT panel 6 communicate with each other. The conductive hole 3 may be defined through manual drilling or electrical drilling. When only a few conductive holes 3 are required, manual drilling can be adopted. When a large number of conductive holes 3 are required, electrical drilling can be adopted.

The conductive hole 3 is filled with a metal-plated material or a conductive glass material. The conductive hole 3 is used for making the electrodes on the two TFT panels 1 communicate with each other. If the conductive hole 3 is filled with a metal-plated material, the metal-plated material can be, but is not limited to, gold, silver, or copper. If the conductive hole 3 is filled with a conductive glass material, the conductive glass may include a volume conductive glass and a surface conductive layer glass. The volume conductive glass contains an alkaline oxide, a silicon oxide, and a titanium oxide. The surface conductive layer glass is manufactured by vapor-depositing a metal film (such as gold, platinum, etc., and the metal film has a thickness of less than 10 nm) on a transparent glass surface, or by spraying a metal oxide conductive film (such as tin, indium, etc.) on a heated glass surface. Therefore, a conductive glass is a glass which is low in resistance and high in conductivity.

A side of one of the two TFT panels 1 is attached to a side of the other one of the two TFT panels 1 with an adhesive insulation material 2. The adhesive insulation material 2 may be, but is not limited to, a polyimide film. Alternatively, the adhesive insulation material 2 may also be other types of adhesive insulation materials. According to different materials of the adhesive insulation material 2, the adhesive insulation material 2 may include an ethylene-propylene rubber self-adhesive tape, an ethylene-propylene rubber and butyl rubber waterproof tape, a silica gel tape, etc. According to different functions of the adhesive insulation material 2, the adhesive insulation material 2 may include a high-pressure rubber self-adhesive tape, a low-pressure rubber self-adhesive tape, a waterproof tape, a semi-conductive tape, an electrical stress control tape, an arc-resistant silica gel tape, etc.

A light emitting component 4 is disposed on the bonding electrode 13 at each of two sides of the double-sided TFT panel 6. The light emitting component 4 can be, but is not limited to, a micro LED, and the size of the micro LED is in the order of micrometers. In addition, the size of the micro LED is less than 100 micrometers. The micro LED on the double-sided TFT panel 6 can emit light under the action of the drive circuit 12.

FIG. 4 is a schematic diagram of a display device 5 having the double-sided TFT panel 6 according to implementations. The display device 5 includes the double-sided TFT panel 6 and a housing 51 configured to fix the double-sided TFT panel 6. It can be understood that, the display device 5 has a display function. The display device 5 includes but is not limited to a monitor, a television, a computer, a notebook computer, a tablet computer, a wearable device, etc.

Apparently, those skilled in the art can make various changes and modifications to the disclosure without departing from the spirit and scope of the disclosure. In this way, if these modifications and variations fall within the scope of the claims of the disclosure and their equivalent technologies, the disclosure is also intended to include these modifications and variations.

The above are only exemplary implementations of the disclosure, which cannot limit the scope of the claims of the disclosure. Therefore, equivalent changes made according to the claims of the disclosure shall also fall within the scope of the disclosure.

What is claimed is:

1. A method for manufacturing a double-sided thin film transistor (TFT) panel, comprising:
providing two substrates, and forming a TFT panel on each of the two substrates;
attaching a support membrane to a side of each TFT panel away from the substrate corresponding to the TFT panel;
peeling off the substrate corresponding to each TFT panel;
forming the double-sided TFT panel, by attaching a side of one of the two TFT panels to a side of the other one of the two TFT panels; and
defining a conductive hole on the double-sided TFT panel, wherein the conductive hole is used for making electrodes on the two TFT panels communicate with each other.

2. The method of claim 1, further comprising:
peeling off the support membrane on the double-sided TFT panel.

3. The method of claim 2, further comprising:
disposing a drive circuit on any one of the two TFT panels of the double-sided TFT panel, wherein the drive circuit is shared with the other one of the two TFT panels of the double-sided TFT panel.

4. The method of claim 1, further comprising:
disposing a light emitting component on a bonding electrode at each of two sides of the double-sided TFT panel.

5. The method of claim 1, wherein peeling off the substrate corresponding to each TFT panel comprises:
peeling off the substrate corresponding to each TFT panel through laser processing.

6. The method of claim 1, wherein forming the double-sided TFT panel, by attaching the side, from which the substrate is peeled off, of each of the two TFT panels comprises:
forming the double-sided TFT panel, by attaching, with an adhesive insulation material, the side, from which the substrate is peeled off, of each of the two TFT panels.

7. The method of claim 1, wherein the adhesive insulation material is a polyimide film.

8. The method of claim 1, wherein the conductive hole is filled with one of a metal-plated material and a conductive glass material.

9. A double-sided thin film transistor (TFT) panel, comprising:
two TFT panels, wherein a side of one of the two TFT panels is attached to a side of the other one of the two TFT panels;
a drive circuit which is disposed on any one of the two TFT panels of the double-sided TFT panel and shared with the other one of the two TFT panels of the double-sided TFT panel; and
a conductive hole defined on the double-sided TFT panel, wherein the conductive hole is used for making electrodes on the double-sided TFT panel communicate with each other.

10. The double-sided TFT panel of claim 9, wherein each of the TFT panel comprises a drive circuit, a bonding electrode, a flat layer, an insulation layer, and a buffer layer; the buffer layer, the insulation layer, and the flat layer are sequentially disposed; the drive circuit is disposed between the insulation layer and the flat layer; the flat layer covers a side of the drive circuit away from the insulation layer; and a side of the flat layer away from the insulation layer forms a flat surface.

11. The double-sided TFT panel of claim 9, further comprising:
a bonding electrode at each of two sides of the double-sided TFT panel; and
a light emitting component on the bonding electrode at each of two sides of the double-sided TFT panel.

12. The double-sided TFT panel of claim 9, wherein a side of one of the two TFT panels is attached to a side of the other one of the two TFT panels with an adhesive insulation material.

13. The double-sided TFT panel of claim 9, wherein the adhesive insulation material is a polyimide film.

14. The double-sided TFT panel of claim 9, wherein the conductive hole is filled with one of a metal-plated material and a conductive glass material.

15. A display device, comprising:
a housing; and
a double-sided TFT panel disposed inside the housing, wherein the double-sided TFT panel comprises:
two TFT panels, wherein a side of one of the two TFT panels is attached to a side of the other one of the two TFT panels;
a drive circuit which is disposed on any one of the two TFT panels of the double-sided TFT panel and shared with the other one of the two TFT panels of the double-sided TFT panel; and
a conductive hole defined on the double-sided TFT panel, wherein the conductive hole is used for making electrodes on the double-sided TFT panel communicate with each other.

16. The display device of claim 14, wherein each of the TFT panel comprises a drive circuit, a bonding electrode, a flat layer, an insulation layer, and a buffer layer; the buffer layer, the insulation layer, and the flat layer are sequentially disposed; the drive circuit is disposed between the insulation layer and the flat layer; the flat layer covers a side of the drive circuit away from the insulation layer; and a side of the flat layer away from the insulation layer forms a flat surface.

17. The display device of claim 14, wherein the double-sided TFT panel further comprises:
a bonding electrode at each of two sides of the double-sided TFT panel; and
a light emitting component on the bonding electrode at each of two sides of the double-sided TFT panel.

18. The display device of claim 14, wherein a side of one of the two TFT panels is attached to a side of the other one of the two TFT panels with an adhesive insulation material.

19. The display device of claim 14, wherein the adhesive insulation material is a polyimide film.

20. The display device of claim 14, wherein the conductive hole is filled with one of a metal-plated material and a conductive glass material.
